(19) United States
(12) Patent Application Publication
(10) Pub. No.: US 2014/0124817 A1
(43) Pub. Date: May 8, 2014

(54) Contact Layers

(71) Applicant: INTERMOLECULAR, INC., San Jose, CA (US)

(72) Inventor: Philip Kraus, San Jose, CA (US)

(73) Assignee: INTERMOLECULAR, INC., San Jose, CA (US)

(21) Appl. No.: 13/669,171

(22) Filed: Nov. 5, 2012

(51) Int. Cl. H01L 21/283; H01L 29/45; H01L 33/42

(52) U.S. Cl. 257/99; 438/609; 257/745; 257/E29.144; 257/E21.159; 257/E33.064

(57) ABSTRACT

An electrical contact is formed on a III-V semiconductor comprising gallium. The contact is formed by depositing a first layer comprising In, Au, and a dopant on the surface of a III-V semiconductor and a second layer comprising a conductive oxide on the first layer. The deposited layers are annealed in an inert atmosphere. The annealing causes the formation of a Ga—Au compound at the interface between the III-V semiconductor and the first layer. At least a portion of the dopant migrates into the III-V semiconductor such that the dopant provides n-type or p-type conductivity to the III-V semiconductor. The specific contact resistivity between the III-V semiconductor and the second layer is less than about 10⁻⁵ Ωcm². The layers are further annealed in an oxidizing atmosphere such that the indium in the first layer is oxidized to form indium oxide.

### FIELD OF THE INVENTION

One or more embodiments of the present invention relate to contact layers at the surface of gallium-containing semiconductors and methods of making the layers.

### BACKGROUND

In order to make contact with optoelectronic devices made from III-V semiconductors, a transparent conducting oxide (TCO) is often used as current spreading layer or a transparent contact layer through which light can be extracted. However, low contact resistance between the TCO layer and the doped semiconductor has not been easy to achieve with TCOs for the commonly used TCOs indium tin oxide (ITO) and indium zinc oxide (IZO).

Contacts to n-type III-V semiconductors, such as GaAs and AlGaInP, are commonly made by using a Ge—Au alloy or a Sn—Au alloy for the contact which is sintered to achieve low specific contact resistivity (˜10⁻⁶ Ωcm²). Contacts to n-type III-V semiconductors can also be made with Si and Sn. Because Ge—Au and Sn—Au contacts are opaque, there is some light output lost due to the fraction of the area covered by the opaque contacts (whether they are arranged in a grid pattern or other pattern). Despite this limitation, opaque Ge—Au alloys are commonly used with III-V semiconductors.

### SUMMARY OF THE INVENTION

An electrical contact is formed on a III-V semiconductor comprising gallium. The layer is formed by depositing a first layer comprising In, Au, and a dopant on the surface of a III-V semiconductor and depositing a second layer comprising a conductive oxide on the first layer. The deposited layers are annealed in an inert atmosphere. The annealing causes the formation of Ga—Au compound at the interface between the III-V semiconductor and the first layer. At least a portion of the dopant migrates into the III-V semiconductor such that the dopant provides n-type conductivity (using Si, Ge, or Sn as dopants) or p-type conductivity (using Be or Mg as dopants) to the III-V semiconductor. The specific contact resistivity from the III-V semiconductor through the first layer is less than about 10⁻⁵ Ωcm². The layers are further annealed in an oxidizing atmosphere such that the indium in the first layer is oxidized to form indium oxide.

The contact layer can form part of an optoelectronic device such as a light emitting diode (LED). The finished contact layer is transparent to light at wavelengths used in the optoelectronic device. In some embodiments, the first layer comprises between 50% and 99% In by atomic percentage. In some embodiments, the first layer comprises about 90% In. In some embodiments, the first layer comprises less than 50% Au by atomic percentage. In some embodiments, the first layer comprises less than 50% Au plus dopant atoms.

In some embodiments, the annealing in an inert atmosphere is omitted, and all atomic migration occurs during the annealing in an oxidizing atmosphere. In some embodiments, the second layer is omitted, and the conductive oxide is formed during the annealing of the first layer in an oxidizing atmosphere. In some embodiments, the second layer is deposited before the annealing step(s). In some embodiments, the second layer is deposited after the annealing step(s).

### BRIEF DESCRIPTION OF THE DRAWINGS

FIG. 1 shows a schematic diagram illustrating one embodiment of the invention.

FIG. 2 shows a schematic diagram illustrating one embodiment of the invention.

FIG. 3 shows a schematic diagram illustrating one embodiment of the invention.

FIG. 4 shows a schematic diagram illustrating one embodiment of the invention.

### DETAILED DESCRIPTION

It must be noted that as used herein and in the claims, the singular forms “a,” “and” and “the” include plural referents unless the context clearly dictates otherwise. Thus, for example, reference to “a dopant” includes two or more dopants, and so forth.

Where a range of values is provided, it is understood that each intervening value, to the tenth of the unit of the lower limit unless the context clearly dictates otherwise, between the upper and lower limit of that range, and any other stated or intervening value in that stated range, is encompassed within the invention. The upper and lower limits of these smaller ranges may independently be included in the smaller ranges, and are also encompassed within the invention, subject to any specifically excluded limit in the stated range. Where the stated range includes one or both of the limits, ranges excluding either or both of those included limits are also included in the invention. The terms “about” and “approximately” generally refers to ±10% of a stated value. The term “substantially all” generally refers to >95% of a total amount.

### Definitions

As used herein, the terms “contact” and “electrical contact” may be used interchangeably, and refers to a structure for making an electrical connection to a semiconductor device. The terms may refer to a complete assembly of components including components intended to reduce contact resistance, spread current laterally, and provide locations for wire bonding, wire bonds, solder bumps or leads and so on. The terms may also be used to refer to one of the components such as a current spreading layer or solder bump.

As used herein, the term “contact resistance” refers generally to the resistance (typically measured in ohms) between components intended to be in electrical contact.

As used herein, the term “specific contact resistivity” refers generally to the material properties related to contact resistance; i.e., the physical dimensions (area) of the contact are removed. The specific contact resistivity is defined as the slope of the V-J curve (i.e., dV/dJ) at V=0, where V is the applied voltage and J is the current flux density (e.g., amperes per cm²). The units of specific contact resistivity are resistance x area (e.g., Ω cm²). If the shape of the V-J curve is linear, an “ohmic contact” is said to exist across the interface.

As used herein, the term “transparent” refers generally to light transmission of at least 90% or preferably at least 95% through a material at wavelengths of interest.

The present invention discloses methods, compositions, and articles of manufacture providing low-resistance contacts for a gallium-containing III-V semiconductor. The contact comprises one or more layers comprising a conductive oxide. The contact layer provides Ga—Au compounds formed near the boundary between the semiconductor and the conductive oxide. Dopants can also be present if desired, enhancing n-type or p-type conductivity near the boundary. Without being bound by theory, it is believed that the Ga—Au compounds formed and the enhanced dopant concentration near the boundary of the III-V semiconductor formed using the inventive methods described herein provide low resistance contact from the III-V semiconductor through the conductive oxide, thereby enhancing performance of optoelectronic devices incorporating these materials.

Methods of forming an electrical contact on a III-V semiconductor are provided, comprising depositing a first layer comprising In, Au, and a dopant on the surface of a III-V semiconductor, and annealing the III-V semiconductor and the first layer. The III-V semiconductor comprises gallium. During annealing, at least a portion of the dopant migrates into the III-V semiconductor to electronically dope or increase the electronic doping of the III-V semiconductor, and at least a portion of the Ga migrates into the first layer to form a compound with the Au. Generally, Ga reacts with Au to form AuGa₂, but other compounds or alloys can be formed depending on the layer compositions and annealing conditions, time, and temperature. The annealing can be performed in an oxidizing atmosphere in order to oxidize the first layer to a conductive oxide Annealing in an inert atmosphere can also be performed prior to annealing in an oxidizing atmosphere.

These process steps provide a method for reducing the contact resistance in an optoelectronic device between a III-V semiconductor layer and a conductive oxide layer. The specific contact resistivity from the III-V semiconductor through the first layer is less than about 10⁻⁵ Ωcm². Contact resistivity can be measured for varying experimental annealing conditions for any particular semiconductor, In and Au content, dopant concentration, conductive oxide, and layer thicknesses to optimize set of composition and conditions for any desired contact resistivity. Combinatorial processing can be employed to explore the parameters systematically.

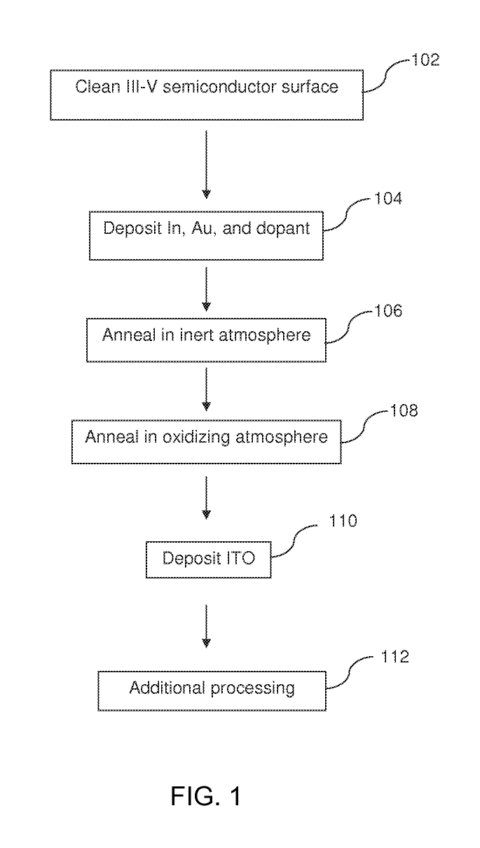

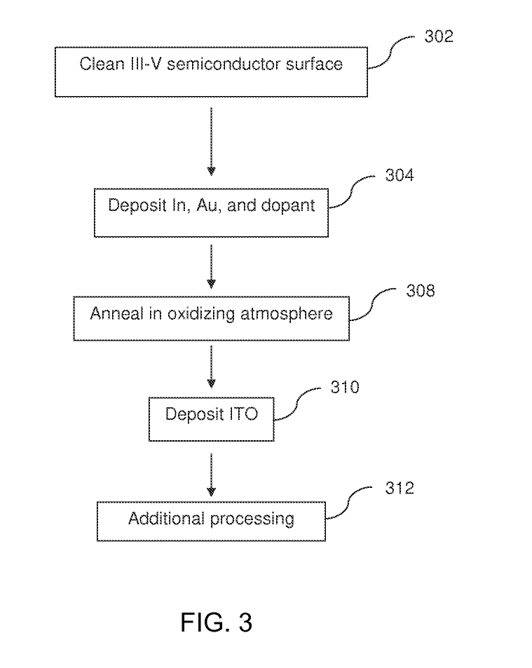

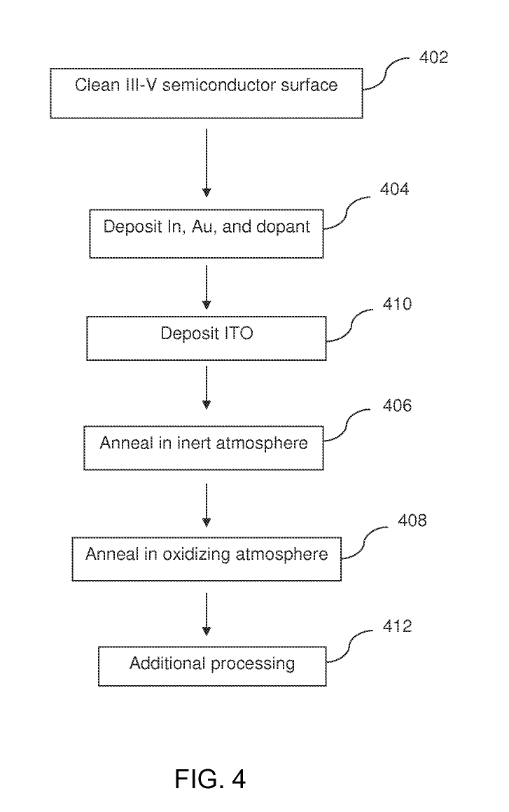

In some embodiments, the method can further comprise depositing a second layer comprising a conductive oxide on the first layer after annealing the first layer in an oxidizing atmosphere, as illustrated in FIGS. 1 and 3, steps 110 and 310. In some embodiments, the method can further comprise depositing a second layer comprising a conductive oxide 410 on the first layer before annealing the first layer in an oxidizing atmosphere. This method is illustrated in FIG. 4. The annealing step in an inert atmosphere 406 can be omitted in some embodiments.

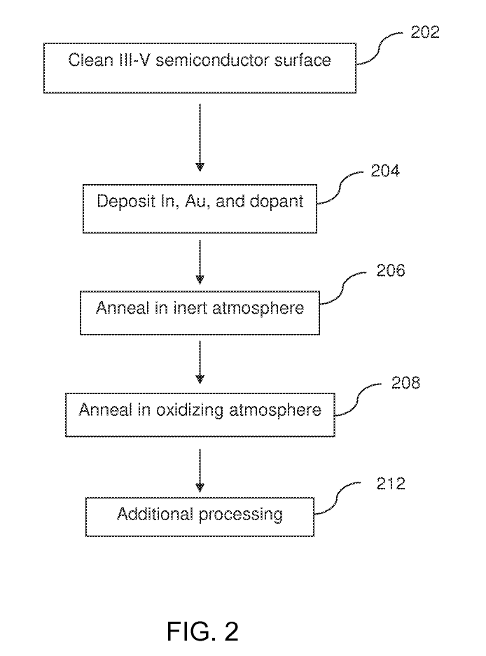

In some embodiments, the second layer is not deposited, as shown in FIG. 2. The method can include annealing the first layer in an inert atmosphere 206 before annealing the first layer in an oxidizing atmosphere 208.

The first layer can comprise between about 50% and 99% In. In some embodiments, the first layer comprises approximately 90% In by atomic percent. The first layer can comprise between 0 and 50% Au, and between 0 and 50% dopant atoms, such that the sum of Au and dopant atomic percentages do not exceed 50%. The second layer comprises a conductive oxide. There is no particular order of deposition of layers required as long as the first layer is disposed between the III-V semiconductor and the second layer and in intimate contact with the III-V semiconductor. In some embodiments, the conductive oxide is transparent to light at operational wavelengths of the optoelectronic device. Typical transparent conductive oxides include indium tin oxide (In₂O₃ with 10% SnO, or “ITO”) or indium zinc oxide (In₂O₃ with 10% ZnO, “IZO”).

The dopants are not particularly limiting and can include any suitable dopant imparting increased conductivity to a III-V semiconductor. For n-type conductivity in typical III-V semiconductors such as GaAs and AlGaInP used for optoelectronic devices, the dopants can comprise Si, Ge, or Sn. For p-type conductivity in the same semiconductors, the dopants can comprise Be or Mg. Typically, the choice of dopant can be selected to match that present in the semiconductor so that the concentration of that dopant can be enhanced near the boundary between the semiconductor and the conductive oxide. In some embodiments, Sn is used as a dopant so that during the annealing treatment in an oxidizing atmosphere, the first layer becomes a transparent conducting oxide (i.e., the In and Sn are oxidized to form the TCO, ITO).

The layers can be deposited by a number of deposition methods, including MOCVD, plasma-enhanced chemical vapor deposition (PECVD), and physical vapor deposition (PVD). In some embodiments, PVD by sputtering is performed.

In some embodiments, two layers are deposited: a first layer comprising In, Au, and a dopant, and a second layer comprising a conductive oxide.

Either one or two annealing steps can be used to enable atomic migration and oxidize the metal in the first layer. If one annealing step is used, it is generally performed in an oxidizing atmosphere, for example, 10% O₂ in Ar. If two annealing steps are used, then a first anneal can be performed in an inert atmosphere (e.g., Ar). The second layer, if desired, can be deposited before or after the annealing steps.

Under suitable annealing conditions, dopants can migrate from the first layer to the semiconductor to increase the conductivity of the semiconductor near the interface, and gallium can migrate from the semiconductor to the first layer to form compounds with the Au in the first layer to increase conductivity near the surface of the semiconductor. The annealing in an oxidizing atmosphere ensures that migration of oxygen from and through the second layer to the first layer oxidizes the indium present in the first layer to form a conductive oxide, and particularly a transparent conductive oxide such as ITO.

In addition to providing source material for atomic migration during annealing, the first layer is thick enough to be continuous, i.e., the first layer is at least one monolayer in thickness. In some embodiments, the first layer is in the range of one to two monolayers in thickness. In some embodiments, the first layer is in the range of two to four monolayers in thickness. In some embodiments, the first layer is in the range of five to ten monolayers in thickness. In addition, the first layer can serve as a barrier layer to protect the semiconductor from plasma damage during the deposition of the second layer.

In some embodiments, the first layer has sufficient thickness to serve as a contact layer without the addition of a second layer comprising a conductive oxide. In these embodiments, the first layer is deposited and is annealed in an oxidizing atmosphere. Annealing in an inert atmosphere can also be performed before or after annealing in an oxidizing atmosphere. These steps are illustrated in FIG. 2. After the annealing step(s), the first layer is a conductive oxide wherein the specific contact resistivity from the III-V semiconductor through the first layer is less than about 10⁻⁵ Ωcm².

The resulting specific contact resistivity from the semiconductor through the first layer can be less than about 10⁻⁵ Ω-cm². In some embodiments, the specific contact resistivity is less than 10⁻⁶ Ω-cm². The specific contact resistivity is generally greater than 10⁻⁹ Ω-cm². In addition to the low resistivity, the annealed contact can be transparent, generally exhibiting a transparency of at least 90% and preferably at least 95% at wavelengths emitted or absorbed by the III-V semiconductor.

Combinatorial processing can be employed to explore the first and second layer parameters systematically, for example, as disclosed in co-pending U.S. patent application Ser. No. 13/339,648, filed on Dec. 29, 2011, co-pending U.S. patent application Ser. No. 13/444,100, filed on Apr. 11, 2012, and IMI patent application entitled “PVD-ALD-CVD HYBRID HPC FOR WORK FUNCTION MATERIAL SCREENING” and having internal attorney docket no. IM0811, each of which is incorporated by reference herein. In particular, a first layer of varying thickness and composition can be deposited on a III-V semiconductor containing gallium and subjected to annealing in an inert atmosphere, an oxidizing atmosphere, or a combination thereof in order to ascertain optimal conditions for desired contact resistivity and transparency. The role of specific dopants can be investigated as well as annealing times and temperatures. In addition, the thickness and composition of the second layer comprising a conductive oxide can be investigated, including how its composition and annealing conditions affect the resulting contact resistivity and transparency. The first and second layers, as well as semiconductor layers, can be deposited by any suitable methods, such as physical vapor deposition, atomic layer deposition, chemical vapor deposition, plasma enhanced atomic layer deposition, or the like, and combinations thereof.

Accordingly, methods of preparing optoelectronic devices incorporating a contact layer exhibiting low specific resistivity are provided. Optoelectronic devices including the inventive contact layers provide lower contact resistance while maintaining high light transmission. The optoelectronic devices are not particularly limited, and can include any device incorporating a III-V semiconductor containing gallium adjacent to a conductive oxide. Typical optoelectronic devices include light emitting devices (e.g., LEDs and lasers) as well as light receiving devices such as photodetectors.

### EXAMPLES

One of ordinary skill in the art will recognize that the present invention can be practiced using a variety of specific embodiments. Layer compositions can vary, the sequence of steps can vary, and processing conditions can vary. Selected steps can be omitted in some embodiments. In the examples below, illustrated schematically in FIGS. 1-4, each process can begin with the optional cleaning of a III-V semiconductor surface by conventional cleaning methods (102, 202, 302, 402). The III-V semiconductor can be, for example, any of the gallium-containing semiconductors commonly used for the manufacture of red, orange, or yellow LEDs. At the conclusion of each example process, optional additional processing steps (112, 212, 312, 412) such as patterning and device integration steps are understood to be followed, again using well-known methods.

The first layer in each of the following examples is taken as having the exemplary composition of 5% Au, 10% Sn, and 85% In by atomic fraction, although it is understood that other dopants and other percentages are possible. Deposition is typically by a physical vapor deposition (PVD) method such as sputtering.

Where an anneal in an inert atmosphere is included, an exemplary protocol comprises heating the layers at 400° C. for 5 min in Ar at atmospheric pressure.

The anneal in an oxidizing atmosphere is exemplified by heating the layers at 500° C. for 5 min at atmospheric pressure in an atmosphere comprising 10% O₂ and 90% Ar.

Where a second layer is deposited, an exemplary composition is indium tin oxide (ITO) comprising 10% Sn and 90% In by atomic fraction, although it will be understood that alternative second layer compositions can be utilized as desired (e.g., different percentages of Sn or Zn instead of Sn). Deposition is typically by PVD.

### Example 1

As shown in FIG. 1, after cleaning 102 the surface of the III-V semiconductor and depositing 104 the first layer, the structure is annealed 106 first in an inert atmosphere to promote atomic migration between the first layer and the III-V semiconductor: Sn migrates into the III-V semiconductor for increased doping and Ga migrates into the first layer to associate with Au. Thereafter, the structure is annealed 108 in an oxidizing atmosphere to oxidize the In in the first layer to form a conductive oxide. The current spreading of the conductive oxide can then be further enhanced by the deposition 110 of a second conductive oxide layer. The first layer provides an additional function as a barrier layer to protect the III-V semiconductor from damage during the deposition of the second layer.

### Example 2

This example is identical to Example 1, except that the second conductive oxide layer is omitted (FIG. 2). The first layer is deposited with sufficient thickness to provide adequate current spreading without the additional conductive oxide layer.

### Example 3

This example is identical to Example 1, except that the anneal in an inert atmosphere is omitted (FIG. 3). The atomic migration occurs instead entirely during the anneal 308 in an oxidizing atmosphere.

### Example 4

This example is identical to Example 1, except that the second conductive oxide layer is deposited 410 before the annealing steps 406 and 408 (See FIG. 4). The annealing step 406 in an inert atmosphere can optionally be omitted. The first layer can still serve to protect the III-V semiconductor from damage during deposition of the conductive oxide. Oxygen migrates from and through the conductive oxide during the annealing step(s) to fully oxidize the In in the first layer.

It will be understood that the descriptions of one or more embodiments of the present invention do not limit the various alternative, modified and equivalent embodiments which may be included within the spirit and scope of the present invention as defined by the appended claims. Furthermore, in the detailed description above, numerous specific details are set forth to provide an understanding of various embodiments of the present invention. However, one or more embodiments of the present invention may be practiced without these specific details. In other instances, well known methods, procedures, and components have not been described in detail so as not to unnecessarily obscure aspects of the present embodiments.

What is claimed is:

1. A method of forming an electrical contact on a III-V semiconductor comprising the steps of
depositing a first layer on the surface of a gallium-containing III-V semiconductor, wherein the first layer comprises In, Au, and a dopant; and
annealing the first layer in an oxidizing atmosphere such that at least a portion of the dopant migrates into the III-V semiconductor and at least a portion of the gallium migrates into the first layer.

2. The method of claim 1, further comprising depositing a second layer comprising a conductive oxide on the first layer before annealing the first layer in an oxidizing atmosphere.

3. The method of claim 1, further comprising depositing a second layer comprising a conductive oxide on the first layer after annealing the first layer in an oxidizing atmosphere.

4. The method of claim 1, further comprising annealing the first layer in an inert atmosphere before annealing the first layer in an oxidizing atmosphere.

5. The method of claim 1, wherein the dopant comprises Si, Ge, or Sn.

6. The method of claim 1, wherein the dopant comprises Be or Mg.

7. The method of claim 1, wherein the specific contact resistivity from the III-V semiconductor through the first layer is less than about 10⁻⁵ Ωcm².

8. The method of claim 1, wherein after annealing the first layer in an oxidizing atmosphere, the first layer is transparent to wavelengths of light emitted by the III-V semiconductor.

9. The method of claim 3, wherein the conductive oxide comprises indium tin oxide or indium zinc oxide.

10. The method of claim 1, wherein the annealing the first layer in an oxidizing atmosphere causes substantially all of the indium in the first layer to be oxidized to form indium oxide.

11. The method of claim 1, wherein the first layer comprises between 50% and 99% In by atomic percentage.

12. The method of claim 1, wherein the first layer comprises approximately 90% In by atomic percentage.

13. The method of claim 1, wherein the first layer comprises less than 50% Au by atomic percentage.

14. A low resistance contact layer made by the method of claim 1.

15. The low resistance contact layer of claim 14, wherein the specific contact resistivity from the III-V semiconductor through the first layer is less than about 10⁻⁵ Ωcm².

16. The low resistance contact layer of claim 14, wherein the first layer comprises between 50% and 99% In by atomic percentage.

17. The low resistance contact layer of claim 14, wherein the first layer comprises approximately 90% In by atomic percentage.

18. The low resistance contact layer of claim 14, wherein the first layer comprises less than 50% Au by atomic percentage.

19. An optoelectronic device comprising the low resistance contact layer of claim 14.

20. The optoelectronic device of claim 19, wherein the optoelectronic device is an LED.
